(19) United States
(12) Patent Application Publication
(10) Pub. No.: US 2021/0403731 A1
(43) Pub. Date: Dec. 30, 2021

(54) MATERIAL COMPOSITION AND MANUFACTURING METHOD OF LIGHT COUPLING LENS FOR QUANTUM DOT DISPLAY PANEL

(71) Applicant: SHENZHEN CHINA STAR OPTOELECTRONICS SEMICONDUTOR DISPLAY TECHNOLOGY CO., LTD., Shenzhen, Guangdong (CN)

(72) Inventors: Ming LIU, Shenzhen, Guangdong (CN); Yuanchun WU, Shenzhen, Guangdong (CN)

(21) Appl. No.: 16/759,276

(22) PCT Filed: Dec. 26, 2019
(86) PCT No.: PCT/CN2019/128644

§ 371 Date: Apr. 24, 2020

(30) Foreign Application Priority Data
Dec. 20, 2019 (CN) 201911321886.9

(51) Int. Cl. C09D 11/101; G02B 1/04; H01L 51/56; H01L 51/50; H01L 51/52; C09D 11/38; C09D 11/106; C09D 11/52; B41M 3/00

(52) U.S. Cl. CPC C09D 11/101; G02B 1/041; H01L 51/56; H01L 51/502; G03F 7/027; C09D 11/38; C09D 11/106; C09D 11/52; B41M 3/003; H01L 51/5275

(57) ABSTRACT

A material composition and a manufacturing method of a light out-coupling lens for a quantum dot display panel are provided. The material composition includes trimethylolpropane tris(3-mercaptopropionate), triethyleneglycol divinyl ether, and an ultraviolet radical initiator. A molar ratio of trimethylolpropane tris(3-mercaptopropionate) to triethyleneglycol divinyl ether is 2:3. The material composition is cured by an ultraviolet light to form the light out-coupling lens. The manufacturing method of the light out-coupling lens includes steps of: mixing trimethylolpropane tris(3-mercaptopropionate) and triethyleneglycol divinyl ether; adding an ultraviolet free-radical initiator to form a material composition of the light out-coupling lens; disposing the material composition on a thin-film encapsulation layer of the quantum dot display panel; and subjecting the material composition to an ultraviolet curing process to form the light out-coupling lens.

### FIELD OF INVENTION

The present application relates to the field of display technologies, and more particularly, to a material composition and a manufacturing method of a light out-coupling lens for a quantum dot display panel.

### BACKGROUND OF INVENTION

Organic light-emitting diodes (OLEDs) possess advantages of self-emission, high contrast, and application to flexible and bended products. OLEDs are thus very promising display technologies. However, OLEDs employ white light as a base light. OLEDs require the disposition of color filters, and combinations of colors present various colors that are visible to human naked eyes. The light intensity of OLEDs depends on the magnitude of current. The greater the current, the greater the energy carried by the electrons, and the higher the brightness of the generated light. Therefore, OLEDs possess disadvantages of high operating temperature, energy consumption, low brightness, and limited color gamut.

Therefore, it is necessary to provide a quantum dot OLED display panel and a manufacturing method thereof to solve the existing problems of high operating temperature, energy consumption, low brightness, and limited color gamut in the prior art.

### Technical Problems

In view of the foregoing, the present disclosure provides a quantum dot OLED display panel and a manufacturing method thereof to solve the existing problems of high operating temperature, energy consumption, low brightness, and limited color gamut in the prior art.

### SUMMARY OF INVENTION

A primary object of the present disclosure is to provide a material composition of a light out-coupling lens, which can form a light out-coupling lens after coating, drying, exposing, developing, heating (or by printing/transferring and curing) processes. The light out-coupling lens can increase the light out-coupling coefficient and enhance a light-emitting efficiency of organic light-emitting diodes (OLEDs). In another aspect, a plurality of quantum dots of the light out-coupling lens can absorb short-wavelength components of white light emitted by OLEDs to emit red light or green light. The quantum dots have a reinforcing effect on brightness of red sub-pixels or green sub-pixels, so that screens become more energy efficient and possess greater brightness and wider color gamut.

A secondary object of the present disclosure is to provide a quantum dot OLED display panel, which employs OLEDs to excite quantum dots to emit light. Quantum dots have advantages of concentrated emission spectrum and high color purity, which can greatly increase color saturation and color gamut. In addition, microstructures (such as prisms, hemispherical lenses, gratings, etc.) can be disposed outside the OLEDs, which can significantly increase out-coupling efficiency.

To achieve the foregoing object of the present disclosure, an embodiment of the present disclosure provides a material composition of a light coupling lens for a quantum dot display panel. The material composition of the light coupling lens includes:

trimethylolpropane tris(3-mercaptopropionate);

triethyleneglycol divinyl ether; and

an ultraviolet free-radical initiator;

wherein a molar ratio of trimethylolpropane tris(3-mercaptopropionate) to triethyleneglycol divinyl ether is 2:3, the material composition is cured by an ultraviolet light to form the light out-coupling lens, a diameter of a bottom of the light out-coupling lens ranges from 30 to 100 micrometers, and a height of the light out-coupling lens ranges from 20 to 80 micrometers.

In an embodiment of the present disclosure, the material composition is formulated as a printing ink and a hemispherical light out-coupling lens is formed after the printing ink is cured.

In an embodiment of the present disclosure, the material composition further comprises a plurality of quantum dots, the quantum dots absorb short wavelengths of white light to emits red light or green light.

In an embodiment of the present disclosure, wherein the material composition further comprises: a photoresist, and a mass ratio of the quantum dots to a solute of the photoresist ranges from 2% to 12%.

In an embodiment of the present disclosure, the quantum dot organic light-emitting diode display panel further comprises an encapsulation layer, a shape of the light out-coupling lens is hemispherical shape, and a plurality of the light out-coupling lenses are arranged in an array on the encapsulation layer.

Furthermore, another embodiment of the present disclosure further provides a manufacturing method of a light out-coupling lens for a quantum dot display panel, comprising steps of:

mixing trimethylolpropane tris(3-mercaptopropionate) and triethyleneglycol divinyl ether in a molar ratio of 2:3;

adding an ultraviolet free-radical initiator to form a material composition of the light out-coupling lens; and

disposing the material composition on a thin-film encapsulation layer of the quantum dot display panel and subjecting the material composition to an ultraviolet curing process to form the light out-coupling lens. In an embodiment of the present disclosure,

In an embodiment of the present disclosure, the manufacturing method further comprises steps of:

blending trimethylolpropane tris(3-mercaptopropionate), triethyleneglycol divinyl ether, and the ultraviolet radical initiator to formulate a printing ink;

printing or transferring the printing ink on the thin-film encapsulation layer; and

curing the printing ink by ultraviolet light to form the light out-coupling lens.

In an embodiment of the present disclosure, the manufacturing method further comprises step of: adding a plurality of quantum dots and a photoresist to the material composition, wherein a mass ratio of the quantum dots and a solute of the photoresist ranges from 2% to 12%.

In an embodiment of the present disclosure, the manufacturing method further comprises step of: thermally processing the light out-coupling lens at 80-100° C., wherein the light out-coupling lens is thermally deformed to form a hemispherical shape.

Furthermore, another embodiment of the present disclosure further provides a material composition of light out-coupling lens for a quantum dot display panel, comprising:

trimethylolpropane tris(3-mercaptopropionate);

triethyleneglycol divinyl ether; and

an ultraviolet free-radical initiator;

wherein a molar ratio of trimethylolpropane tris(3-mercaptopropionate) to triethyleneglycol divinyl ether is 2:3 and the material composition is cured by an ultraviolet light to form the light out-coupling lens.

In an embodiment of the present disclosure, the material composition is formulated as a printing ink and a hemispherical light out-coupling lens is formed after the printing ink is cured.

In an embodiment of the present disclosure, the material composition further comprises a plurality of quantum dots, the quantum dots absorb short wavelengths of white light to emits red light or green light.

In an embodiment of the present disclosure, the material composition further comprises: a photoresist, and a mass ratio of the quantum dots to a solute of the photoresist ranges from 2% to 12%.

In an embodiment of the present disclosure, the quantum dot organic light-emitting diode display panel further comprises an encapsulation layer, a shape of the light out-coupling lens is hemispherical shape, and a plurality of the light out-coupling lens are arranged in an array on the encapsulation layer.

Beneficial Effects:

Compared with the prior art, the material composition of the light out-coupling lens of the present disclosure can form a light out-coupling lens after coating, drying, exposing, developing, heating (or by printing/transferring and curing) processes. The light out-coupling lens can increase the light out-coupling coefficient and enhance a light-emitting efficiency of organic light-emitting diodes (OLEDs). In another aspect, a plurality of quantum dots of the light out-coupling lens can absorb short-wavelength components of white light emitted by OLEDs to emit red light or green light. The quantum dots have a reinforcing effect on brightness of red sub-pixels or green sub-pixels, so that screens become more energy efficient and possess greater brightness, wider color gamut, and greater out-coupling efficiency. The quantum dot OLED display panel of the present disclosure employs OLEDs to excite quantum dots to emit light. Quantum dots have advantages of concentrated emission spectrum and high color purity, which can greatly increase color saturation and color gamut. In addition, both monomers of trimethylolpropane tris(3-mercaptopropionate) and triethyleneglycol divinyl ether have low toxicity, low corrosion to the printer head, and a viscosity suitable for the printing process. Quantum dots are allowed to disperse evenly. Therefore, the resulted light out-coupling lens possesses a fine light transmittance and stability.

### DESCRIPTION OF DRAWINGS

For a better understanding of the aforementioned content of the present invention, preferable embodiments are illustrated in accordance with the attached figures for detailed explanation.

FIG. 1 is a schematic structural diagram of a quantum dot display panel according to a first embodiment of the present disclosure.

FIG. 2 is a schematic diagram of a light emission of the quantum dot display panel according to the first embodiment of the present disclosure.

FIG. 3 is a flowchart of a manufacturing method of a light out-coupling lens of the quantum dot display panel according to the first embodiment of the present disclosure.

FIG. 4 is a flowchart of a manufacturing method of a light out-coupling lens of a quantum dot display panel according to a second embodiment of the present disclosure.

FIG. 5 is a schematic diagram of the light out-coupling lens 201 after performing the inkjet-printing process of the material composition according to the manufacturing method of the second embodiment of the present disclosure.

FIG. 6 is a flowchart of a manufacturing method of a light out-coupling lens of a quantum dot display panel according to a third embodiment of the present disclosure.

FIG. 7 is a schematic diagram of manufacturing a light out-coupling layer according to the manufacturing method of the third embodiment of the present disclosure.

FIG. 8 is a schematic diagram of the light out-coupling layer after performing a patterning process according to the manufacturing method of the third embodiment of the present disclosure.

FIG. 9 is a schematic diagram of the light out-coupling layer after performing a thermal processing according to the manufacturing method of the third embodiment of the present disclosure.

### DETAILED DESCRIPTION OF PREFERRED EMBODIMENTS

In the following detailed description, reference is made to the accompanying figures, in which various examples are shown by way of illustration. In this regard, directional terminology mentioned in the present disclosure, such as “top”, “bottom”, “front”, “back”, “left”, “right”, “inner”, “outer”, “lateral”, “side”, “surrounding”, “center”, “horizontal”, “transverse”, “vertical”, “longitudinal”, “axial”, “radial”, “uppermost” or “lowermost”, etc., is used with reference to the orientation of the figures being described. Therefore, the directional terminology is used for purposes of illustration and is not intended to limit the present disclosure. In the accompanying figures, units with similar structures are indicated by the same reference numbers.

The terms “comprise”, “includes”, and their conjugates mean “including but not limited to”.

The terms “a”, “an” and “at least one of” as used herein include plural references unless the context clearly dictates otherwise. For example, the term “a processing module” or “at least one processing module” may include a plurality of processing modules, including combination thereof.

It is noted that the terms “a plurality of” and “several” as used herein may be selected from two, three, or more unless the context clearly dictates otherwise and “at least one” may be selected from one, two, three, or more unless otherwise indicated.

As used herein with reference to size or value are not intended to be construed as an inflexible limitation to the precise values. On the contrary, unless otherwise indicated, the various sizes are intended to represent the recited numerical values as well as the functionally equivalent ranges thereof. For example, a disclosed size of “10 micrometers” refers to “about 10 micrometers”.

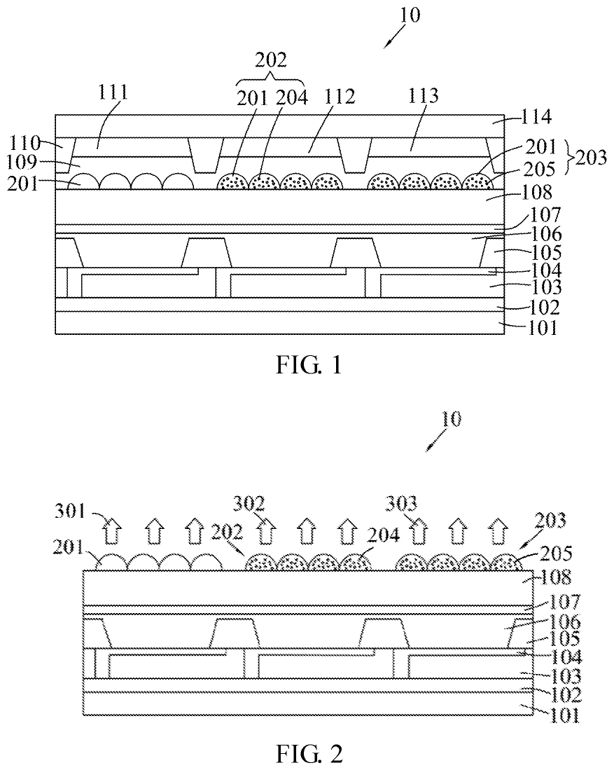

Please refer to FIGS. 1-2. FIG. 1 is a schematic structural diagram of a quantum dot display panel according to a first embodiment of the present disclosure. FIG. 2 is a schematic diagram of a light emission of the quantum dot display panel according to the first embodiment of the present disclosure.

The quantum dot display panel 10 includes a light coupling lens 201. The quantum dot display panel 10 may be a quantum dot organic light-emitting diode display panel.

In the first embodiment of the present disclosure, the quantum dot display panel 10 may further include a substrate 101, a thin-film transistor (TFT) array 102, a planarization layer 103, an anode 104, a pixel defining layer 105, an organic light-emitting diode (OLED) 106, a cathode 107, a thin-film encapsulation layer 108, a black matrix 110, and a cover plate 114 which are formed on the substrate 101 in sequence.

The material composition of the light out-coupling lens 201 includes trimethylolpropane tris(3-mercaptopropionate), triethyleneglycol divinyl ether, and an ultraviolet radical initiator. A molar ratio of trimethylolpropane tris(3-mercaptopropionate) to triethyleneglycol divinyl ether is 2:3. The material composition is cured by an ultraviolet light to form the light out-coupling lens.

Trimethylolpropane tris(3-mercaptopropionate) and triethyleneglycol divinyl ether can be obtained by any known manufacturing method or are commercially available.

The ultraviolet radical initiator may be 1-hydroxycyclohexylphenyl ketone, which may be obtained by any known manufacturing method or commercially. The mass ratio of the ultraviolet radical initiator is 2%. The ultraviolet radical initiator may be 1-hydroxycyclohexylphenyl ketone.

The subtract 101 and the cover plate 114 can be transparent insulating materials, such as transparent insulating materials made of glass, plastic, or ceramic materials. If the subtract 101 is a plastic substrate, the material is, for example, polyethylene terephthalate, polyester, polycarbonate, polyacrylate, or polystyrene.

As shown in FIG. 2, the material composition is disposed on the thin-film transistor array 102, specifically, on the encapsulation layer 108. The material composition may be arranged in an array on each pixel to increase an intensity of white light 301 emitted by the OLED 106.

The material composition may further include a plurality of quantum dots 204, 205, and a mass ratio of the quantum dots 204, 205 ranges from 2% to 10%.

In the first embodiment of the present disclosure, the quantum dots 204, 205 may be red light-emitting quantum dots or green light-emitting quantum dots. In another embodiment of the present disclosure, the quantum dots 204, 205 may be red quantum dots or green quantum dots. Alternatively, in another embodiment of the present disclosure, the quantum dots 204, 205 absorb a short wavelength of white light to emit red light or green light.

The light out-coupling lens 201 having a plurality of red light-emitting quantum dots or a plurality of red quantum dots is a red light out-coupling lens 202. The light out-coupling lens 201 having a plurality of green light-emitting quantum dots or green quantum dots is green light coupling lens 203.

In an embodiment of the present disclosure, a material composition of the light out-coupling lens 201 is transparent.

In another embodiment of the present disclosure, the light out-coupling lens 201 filters white light emitted by the organic light-emitting diode 106 and only allows blue light to pass through. The material composition of the light out-coupling lens 201 and the quantum dots 204, 205 are mixed to allow red light 302 or green light 303 to pass through.

In another embodiment of the present disclosure, by adjusting a radius of the quantum dots 204, 205, the quantum dots 204, 205 emit red light 302 or green light 303. The less the radius of the quantum dots 204, 205, the less the wavelength of light emission (blue shift), the greater the radius of the quantum dots 204, 205, and the greater the wavelength of light emission (red shift).

In another embodiment of the present disclosure, the quantum dots 204, 205 are suitable for absorbing an incident light having a first spectrum. The quantum dots 204, 205 re-emit the absorbed incident light into an emergent light having a second spectrum. For example, the incident light is white light and the emergent light is red light or green light. For example, the incident light is blue light and the emergent light is red light or green light.

The quantum dots 204, 205 can be obtained by any known manufacturing method or are commercially available, for example, CdSe quantum dot, ZnS quantum dot, CdTe quantum dot, PbTe quantum dot, ZnSe quantum dot, Si quantum dot, Ge quantum dot, or PbSe quantum dot.

The material composition of the light out-coupling lens is formulated as a printing ink. A hemispherical light out-coupling lens 201 is formed after the printing ink is cured. A diameter of a bottom of the light out-coupling lens 201 ranges from 30 to 100 micrometers and a height ranges from 20 to 80 micrometers. The diameter and the height can be adjusted according to process requirements.

The material composition of the light out-coupling lens further includes a photoresist. A mass ratio of the quantum dots 204, 205 to a solute of the photoresist ranges from 2% to 12%.

The substrate may be a transparent insulating material, such as a transparent insulating material of glass, plastic, or ceramic material. If the substrate is a plastic substrate, the material is, for example, polyethylene terephthalate, polyester, polycarbonate, polyacrylate, or polystyrene.

The thin-film transistor array 102 may be selected from the group consisting of a low temperature polysilicon thin-film transistor (LTPS-TFT), an amorphous silicon thin-film transistor (a-Si: HTFT), and an organic thin-film transistor (OTFT).

A suitable material of the planarization layer 103 is an insulating material of oxide, nitride, carbide, or combinations thereof, such as silicon nitride, silicon oxide, aluminum oxide, magnesium oxide, aluminum nitride, or magnesium fluoride.

The anode 104 may be a reflective anode 104, for example, indium tin oxide (ITO)/silver (Ag)/indium tin oxide. The cathode 107 may be a transparent cathode or a translucent cathode, such as a thin layer of a magnesium silver (MgAg) alloy.

The pixel defining layer 105 separates the organic light-emitting diode 106 to define a plurality of pixels.

The organic light-emitting diode 106 can include a light-emitting layer, a hole transport layer, and an electron transport. The light-emitting layer may include any known organic electroluminescent material, including but not limited to, polymer-based materials, small molecule-based materials, and dendrimer-based materials. The hole-transporting layer and the electron-transporting layer can employ any conventional materials, depending on the type of the used organic electroluminescent material.

The thin-film encapsulation layer 108 may be a stacked structure of silicon oxide and/or silicon oxynitride.

The cover plate 114 (as shown in FIG. 1) may be provided with color filters 111, 112, and 113 to form a plurality of sub-pixels. The color filters 111, 112, and 113 can be selected from the group consisting of a blue filter 111, a red filter 112, and a green filter 113. The black matrix 110 and the color filter films 111, 112, and 113 are spaced apart to prevent different colors of light from being scattered or refracted and mixed with each other.

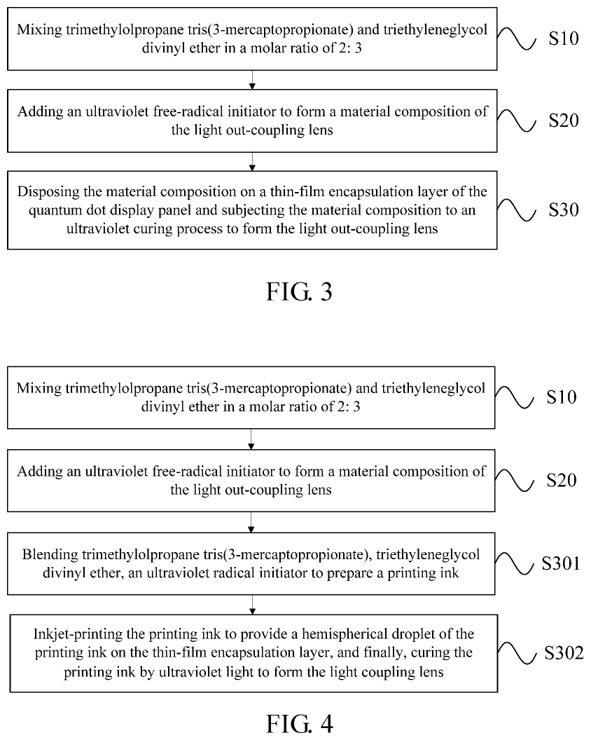

Please refer to FIG. 3. FIG. 3 is a flowchart of a manufacturing method of a light out-coupling lens of the quantum dot display panel according to a first embodiment of the present disclosure. The present disclosure provides a manufacturing method of light out-coupling lens of the quantum dot display panel 10. The manufacturing method includes,

a step S10 of mixing trimethylolpropane tris(3-mercaptopropionate) and triethyleneglycol divinyl ether in a molar ratio of 2:3;

a step S20 of adding an ultraviolet free-radical initiator to form a material composition of the light out-coupling lens; and

a step S30 of disposing the material composition on a thin-film encapsulation layer 108 of the quantum dot display panel 10 and subjecting the material composition to an ultraviolet curing process to form the light out-coupling lens 201, 202, and 203.

In an embodiment of the present disclosure, a plurality of quantum dots 204, 205 (see FIG. 2) can be added to the material composition. A mass ratio of the quantum dots 204, 205 ranges from 2% to 10%. Trimethylolpropane tris(3-mercaptopropionate), triethyleneglycol divinyl ether, and the quantum dots 204, 205 are prepared by solution blending.

In an embodiment of the present disclosure, the quantum dots 204, 205 may be pre-blended with a photoresist. The mass ratio of the quantum dots 204, 205 and the photoresist is 2% or 12%.

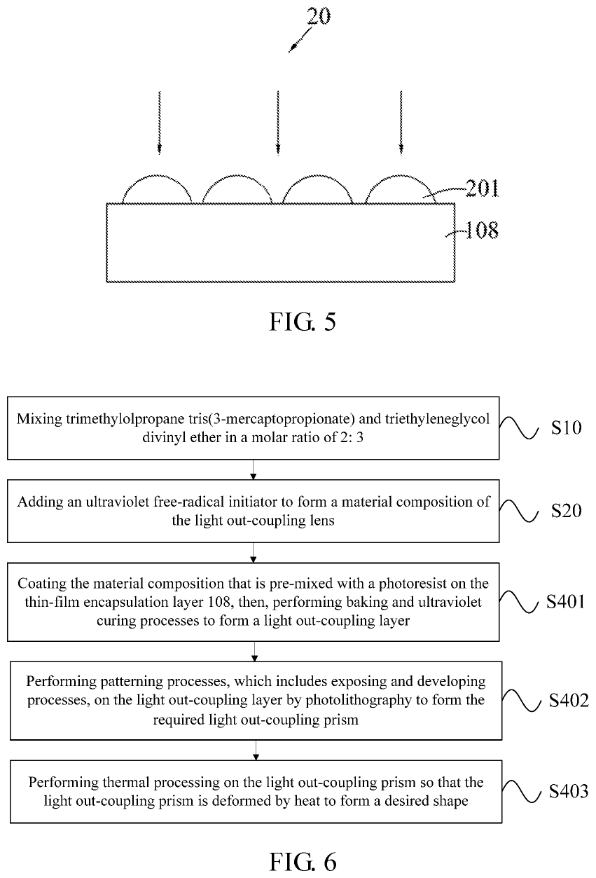

Please refer to FIGS. 4-5. FIG. 4 is a flowchart of a manufacturing method of a light out-coupling lens of a quantum dot display panel according to a second embodiment of the present disclosure. FIG. 5 is a schematic diagram of the light out-coupling lens 201 after performing the inkjet-printing process of the material composition according to the manufacturing method of the second embodiment of the present disclosure.

FIGS. 4-5 show the light out-coupling structure 20 of a second embodiment of the present disclosure. The manufacturing method of the light out-coupling lens 201 includes printing (or transferring) on the thin-film encapsulation layer 108 to provide the light out-coupling composition. The manufacturing method of the light out-coupling lens 201 specifically includes:

a step S301 of blending trimethylolpropane tris(3-mercaptopropionate), triethyleneglycol divinyl ether, an ultraviolet radical initiator, (optionally) a plurality of quantum dots 204, 205 (see FIG. 2), and (optionally) a photoresist to prepare a printing ink; and

a step S302 of inkjet-printing the printing ink to provide a hemispherical droplet of the printing ink on the thin-film encapsulation layer 108, as shown in FIG. 5, and finally, curing the printing ink by ultraviolet light (arrow in FIG. 5) to form the light coupling lens 201. If a transferring process is employed, firstly, the printing ink is printed on a surface of a transfer wheel or a transfer plate to provide a hemispherical droplet of printing ink. After being partially cured by ultraviolet light, the printing ink is transferred onto the thin-film encapsulation layer 108. Finally, after being completely cured by the ultraviolet light, a light out-coupling lens 201 can also be formed on the thin-film encapsulation layer 108.

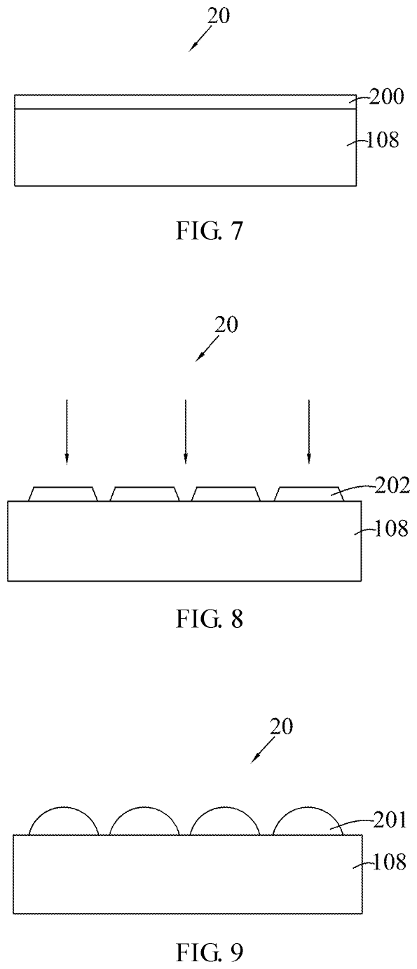

Please refer to FIGS. 6-9. FIG. 6 is a flowchart of a manufacturing method of a light out-coupling lens of a quantum dot display panel according to a third embodiment of the present disclosure. FIG. 7 is a schematic diagram of manufacturing a light out-coupling layer according to the manufacturing method of the third embodiment of the present disclosure. FIG. 8 is a schematic diagram of the light out-coupling layer after performing a patterning process according to the manufacturing method of the third embodiment of the present disclosure. FIG. 9 is a schematic diagram of the light out-coupling layer after performing a thermal processing according to the manufacturing method of the third embodiment of the present disclosure.

FIGS. 7-9 show a light out-coupling structure 20 according to the third embodiment of the present disclosure. The manufacturing method of the light out-coupling lens 201 includes forming an array of light out-coupling lenses on the thin-film encapsulation layer 108 after performing coating, drying, exposing, developing, heating (or by printing/transferring and curing) processes in sequence. The steps are specifically as follows:

a step S401 of coating the material composition that is pre-mixed with a photoresist and (optionally) a plurality of quantum dots 204, 205 (see FIG. 2) on the thin-film encapsulation layer 108, and, then, performing baking and ultraviolet curing processes to form a light out-coupling layer 200, as shown in FIG. 7. This step can be repeated 3 times to form light coupling output layers 200 containing red light-emitting quantum dots 204, green light-emitting quantum dots 205, without quantum dots 204, 205 at predetermined positions of the red, green, and blue sub-pixels.

a step S402 of performing patterning processes, which includes exposing and developing processes (arrows in FIG. 8), on the light out-coupling layer 200 by photolithography to form the required light out-coupling prism 202, as shown in FIG. 8.

a step S403 of performing thermal processing on the light out-coupling prism 202, as shown in FIG. 9. For example, the light out-coupling prism 202 is thermally processed at 80-100° C., so that the light out-coupling prism 202 is appropriately deformed by heat to form a desired shape, such as a hemispherical shape, a prismatic shape, or a grating.

The photolithography process is one kind of patterning processes, and, for example can comprise: steps of preprocessing, forming a base film, coating, baking a photoresist, exposing, developing, etching and others. For example, the preprocessing commonly includes steps of wet cleaning, deionized water cleaning, dewatering baking and others; for example, the base film forming can be achieved by using vapor deposition, magnetron sputtering and other methods; for example, the photoresist coating can be achieved through static adhesive coating or dynamic adhesive coating; the baking can be used for removing a solvent in photoresist or a solvent after the developing step. Besides, the photolithography process can also comprise: steps hardening baking, developing inspection and others. Steps in the photolithography process which are used when a white photoresist layer and a black photoresist layer are formed and the number of using the steps are not limited in the description, as long as the white photoresist layer and the black photoresist layer can be formed. For example, the photolithography process can also comprise several of the above steps. For example the photolithography process comprises photoresist coating, the exposing, developing and other steps.

Compared with the prior art, the material composition of the light out-coupling lens in the quantum dot display panel of the present disclosure can form a light out-coupling lens after coating, drying, exposure, development, heating (or by printing/transferring and curing) processes. The light out-coupling lens can increase the light out-coupling coefficient and enhance a light-emitting efficiency of organic light-emitting diodes (OLEDs). In another aspect, a plurality of quantum dots of the light out-coupling lens can absorb short-wavelength components of white light emitted by OLEDs to emit red light or green light. The quantum dots have a reinforcing effect on brightness of red sub-pixels or green sub-pixels, so that screens become more energy efficient and possess greater brightness, wider color gamut, and greater out-coupling efficiency. The quantum dot display panel of the present disclosure employs OLEDs to excite quantum dots to emit light. Quantum dots have advantages of concentrated emission spectrum and high color purity, which can greatly increase color saturation and color gamut. In addition, both monomers of trimethylolpropane tris(3-mercaptopropionate) and triethyleneglycol divinyl ether have low toxicity, low corrosion to the printer head, and a viscosity suitable for the printing process. Quantum dots are allowed to disperse evenly. Therefore, the resulted light out-coupling lens possesses a fine light transmittance and stability.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

1. A material composition of a light out-coupling lens for a quantum dot display panel, comprising:
trimethylolproparie tris(3-mercaptopropionate);
triethyleneglycol divinyl ether; and
an ultraviolet free-radical initiator;
wherein a molar ratio of trimethylolpropane tris(3-mercaptopropionate) to triethyleneglycol divinyl ether is 2:3, the material composition is cured by an ultraviolet light to form the light out-coupling lens, a diameter of a bottom of the light out-coupling lens ranges from 30 to 100 micrometers, and a height of the light out-coupling lens ranges from 20 to 80 micrometers.

2. The material composition of claim 1, wherein the material composition is formulated as a printing ink and a hemispherical light out-coupling lens is formed after the printing ink is cured.

3. The material composition of claim 1, wherein the material composition further comprises a plurality of quantum dots, the quantum dots absorb short wavelengths of white light to emits red light or green light.

4. The material composition of claim 1, wherein the material composition further comprises: a photoresist, and a mass ratio of the quantum dots to a solute of the photoresist ranges from 2% to 12%.

5. The material composition of claim 1, wherein the quantum dot display panel further comprises an encapsulation layer, a shape of the light out-coupling lens is hemispherical shape, and a plurality of the light out-coupling lenses are arranged in an array on the encapsulation layer.

6. A manufacturing method of a light out-coupling lens for a quantum dot display panel, comprising steps of:
mixing trimethylolpropane tris(3-mercaptopropionate) and triethyleneglycol divinyl ether in a molar ratio of 2:3;
adding an ultraviolet free-radical initiator to form a material composition of the light out-coupling lens; and
disposing the material composition on a thin-film encapsulation layer of the quantum dot display panel and subjecting the material composition to an ultraviolet curing process to form the light out-coupling lens.

7. The manufacturing method of claim 6, wherein the manufacturing method further comprises steps of:
blending trimethylolpropane tris(3-mercaptopropionate), triethyleneglycol divinyl ether, and the ultraviolet radical initiator to formulate a printing ink;
printing or transferring the printing ink on the thin-film encapsulation layer; and
curing the printing ink by ultraviolet light to form the light out-coupling lens.

8. The manufacturing method of claim 6, wherein the manufacturing method further comprises step of: adding a plurality of quantum dots and a photoresist to the material composition, wherein a mass ratio of the quantum dots and a solute of the photoresist ranges from 2% to 12%.

9. The manufacturing method of claim 6, wherein the manufacturing method further comprises step of: thermally processing the light out-coupling lens at 80-100° C. wherein the light out-coupling lens is thermally deformed to form a hemispherical shape.

10. A material composition of light out-coupling lens for a quantum dot display panel, comprising:
trimethylolpropane tris(3-mercaptopropionate);
triethyleneglycol divinyl ether; and
an ultraviolet free-radical initiator;
wherein a molar ratio of trimethylolpropane tris(3-mercaptopropionate) to triethyleneglycol divinyl ether is 2:3 and the material composition is cured by an ultraviolet light to form the light out-coupling lens.

11. The material composition of claim 10, wherein the material composition is formulated as a printing ink and a hemispherical light out-coupling lens is formed after the printing ink is cured.

12. The material composition of claim 10, wherein the material composition further comprises a plurality of quantum dots, the quantum dots absorb short wavelengths of white light to emits red light or green light.

13. The material composition of claim 10, wherein the material composition further comprises: a photoresist, and a mass ratio of the quantum dots to a solute of the photoresist ranges from 2% to 12%.

14. The material composition of claim 10, wherein the quantum dot display panel further comprises an encapsulation layer, a shape of the light out-coupling lens is hemispherical shape, and a plurality of the light out-coupling lens are arranged in an array on the encapsulation layer.
